(19) United States
(12) Patent Application Publication
(10) Pub. No.: US 2011/0085152 A1
(43) Pub. Date: Apr. 14, 2011

(54) Vibration control apparatus, vibration control method, exposure apparatus, and device manufacturing method

(76) Inventors: Hideaki Nishino, Kamakura-shi (JP); Hiroshi Shirasu, Yokohama-shi (JP)

(21) Appl. No.: 12/775,022

(22) Filed: May 6, 2010

(30) Foreign Application Priority Data
May 7, 2009 (JP) P2009-112559

(51) Int. Cl. G03B 27/58; F16F 7/00; G03F 7/20

(52) U.S. Cl. 355/72; 248/636; 430/325

(57) ABSTRACT

A vibration control apparatus suppresses a vibration of a structure which is vibrated. The vibration control apparatus includes: a vibration isolation apparatus that supports the structure and suppresses a transmission of a vibration to the structure, the vibration having an amplitude equal to or less than a first amplitude in a predetermined direction; and a damping apparatus that damps a vibration of the structure vibrating in the predetermined vibration direction with a second amplitude larger than the first amplitude, to thereby reduce the vibration to equal to or less than the first amplitude.

### CROSS-REFERENCE TO RELATED APPLICATION

This application claims priority to Japanese Patent Application No. 2009-112559, filed on May 7, 2009. The entire contents of which are incorporated herein by reference.

### BACKGROUND

1. Technical Field

The present invention relates to a vibration control apparatus, a vibration control method, an exposure apparatus, and a device manufacturing method.

2. Background Art

In a manufacturing process of semiconductor devices, electronic devices, or the like, an exposure apparatus such as is disclosed in, for example, Japanese Unexamined Patent Application, First Publication No. 2000-77313 is used.

In the case where a heavy vibration attending, for example, an earthquake or the like acts on an exposure apparatus, there is a possibility that a serious damage occurs in the exposure apparatus.

### SUMMARY

Aspects of the present invention have an object to provide a vibration control apparatus, a vibration control method, an exposure apparatus, and a device manufacturing method that are capable of suppressing an occurrence of damage even in the case where a heavy vibration attending an earthquake or the like is produced.

According to a first aspect of the present invention, there is provided a vibration control apparatus that controls a vibration of a structure, the apparatus comprising: a vibration isolation apparatus that supports the structure and suppresses a transmission of a vibration to the structure, the vibration having an amplitude equal to or less than a first amplitude in a predetermined direction; and a damping apparatus that damps a vibration of the structure vibrating in the predetermined vibration direction with a second amplitude larger than the first amplitude, to thereby reduce the vibration to equal to or less than the first amplitude.

According to a second aspect of the present invention, there is provided a vibration control method of controlling a vibration of a structure, the method comprising: supporting the structure, and also suppressing transmission of a vibration with an amplitude equal to or less than a first amplitude in a predetermined vibration direction to the structure; and damping a vibration of the structure that is vibrated with a second amplitude larger than the first amplitude in the vibration direction to a vibration with an amplitude equal to or less than the first amplitude.

According to a third aspect of the present invention, there is provided an exposure apparatus that transfers a pattern formed on a mask onto a substrate, including: a first support portion that supports a pattern holding member provided with the pattern; a second support portion that supports the substrate: a projection optical system that projects an image of the pattern onto the substrate; a structure that supports at least one of the first support portion, the second support portion, and the projection optical system; and the vibration control apparatus of the first aspect for controlling a vibration of the structure.

According to a fourth aspect of the present invention, there is provided an exposure apparatus that transfers a pattern formed on a mask onto a substrate, including: a first support portion that supports a pattern holding member provided with the pattern; a second support portion that supports the substrate: a structure that supports at least one of the first support portion and the second support portion; and the vibration control apparatus of the first aspect for controlling a vibration of the structure.

According to a fifth aspect of the present invention, there is provided a device manufacturing method, including: transferring the pattern onto the substrate by use of the exposure apparatus of the second or third aspect; and treating the substrate onto which the pattern is transferred, correspondingly to the pattern.

According to the aspects of the present invention, it is possible to suppress an occurrence of damage even in the case where a heavy vibration attending an earthquake or the like is produced.

### BRIEF DESCRIPTION OF THE DRAWINGS

FIG. 1 is a schematic block diagram showing an example of an exposure apparatus according to a present embodiment.

FIG. 2 is a diagram showing an example of positional relationship between a vibration control apparatus and a body according to the present embodiment.

FIG. 3 is a diagram showing an example of an exposure apparatus according to the present embodiment.

FIG. 4 is a diagram showing an example of a vibration isolation apparatus according to the present embodiment.

FIG. 5 is a diagram showing an example of a damping apparatus according to the present embodiment.

FIG. 6 is a diagram showing an example of operation of the damping apparatus according to the present embodiment.

FIG. 7 is a diagram showing an example of operation of the damping apparatus according to the present embodiment.

FIG. 8 is a flow chart explaining an example of a manufacturing process for a micro device.

### DESCRIPTION OF EMBODIMENTS

Hereunder is a description of an embodiment of the present invention with reference to the drawings. However, the present invention is not limited to this description. In the following description, an XYZ rectangular co-ordinate system is established, and the positional relationship of respective portions is described with reference to this XYZ rectangular co-ordinate system. A predetermined direction within a horizontal plane is made the X axis direction, a direction orthogonal to the X axis direction in the horizontal plane is made the Y axis direction, and a direction orthogonal to both the X axis direction and the Y axis direction (that is, a perpendicular direction) is made the Z axis direction. Furthermore, rotation (inclination) directions about the X axis, the Y axis and the Z axis, are made the θX, the θY, and the θZ directions respectively.

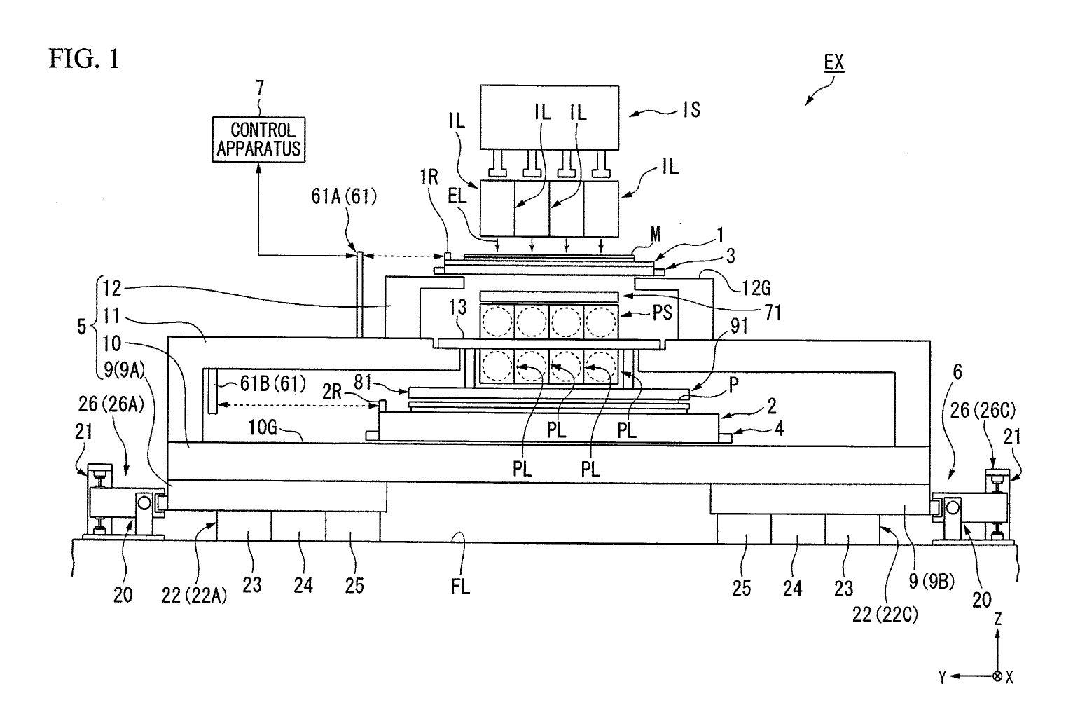

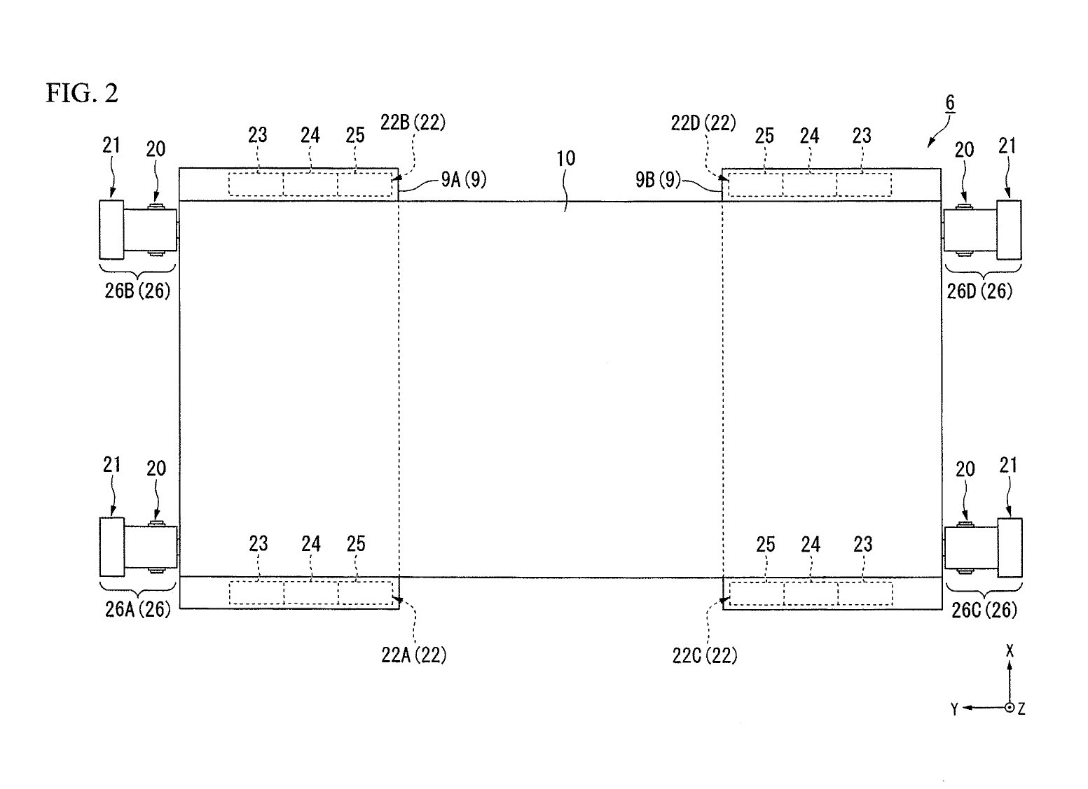

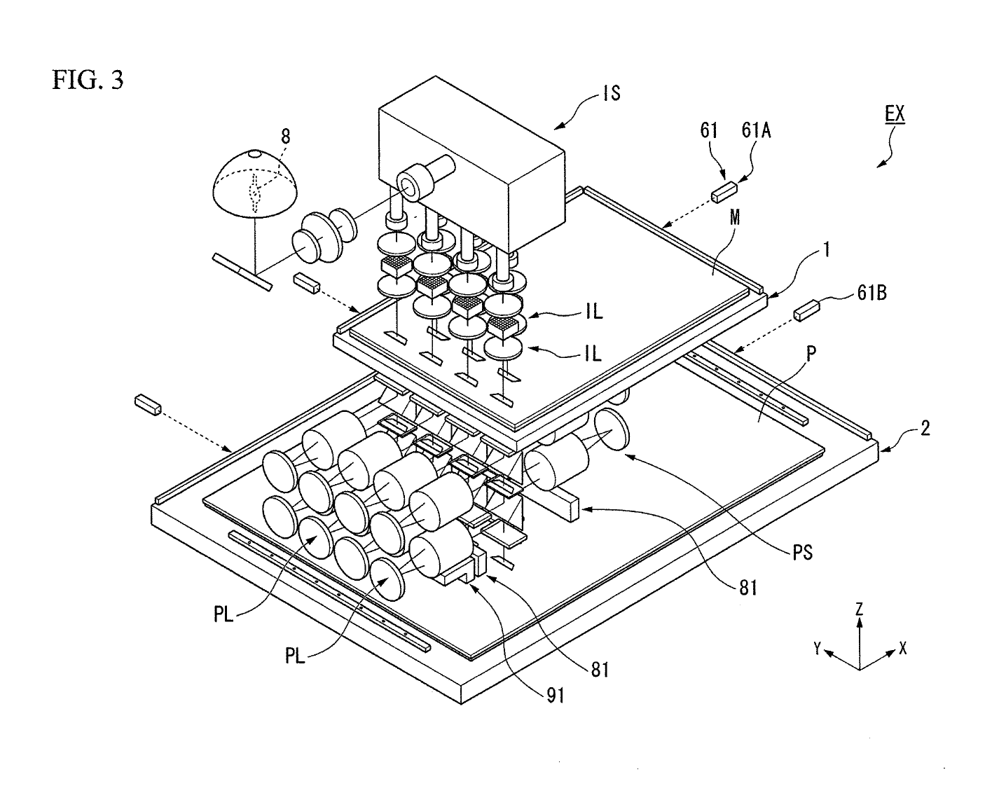

FIG. 1 is a schematic block diagram showing an example of an exposure apparatus EX provided with a vibration control apparatus 6 according to the present embodiment. FIG. 2 is a plan view showing a positional relationship between the vibration control apparatus 6 according to the present embodiment and a body 5 whose vibration is controlled by the vibration control apparatus 6. FIG. 3 is a perspective view showing an example of the exposure apparatus EX according to the present embodiment.

In FIG. 1, FIG. 2, and FIG. 3, the exposure apparatus EX is provided with: a mask stage 1 capable of moving while holding a mask M provided with a pattern; a substrate stage 2 capable of moving while supporting a substrate P; a drive system 3 for moving the mask stage 1; a drive system 4 for moving the substrate stage 2; an illumination system IS for illuminating the mask M with exposure beams EL; a projection system PS for projecting an image of the pattern of the mask M illuminated by the exposure beams EL onto the substrate P; a body 5 for supporting at least one of the mask stage 1, the substrate stage 2, and the projection system PS; a vibration control apparatus 6 for suppressing a vibration of the body 5; and a control apparatus 7 for controlling operation of the whole exposure apparatus EX.

Furthermore, the exposure apparatus EX of the present embodiment is provided with: an interference system 61 for measuring position information of the mask stage 1 and the substrate stage 2; a first detection system 71 for detecting position information of a surface of the mask M (a bottom surface, a pattern forming surface); a second detection system 81 for detecting position information of a surface of the substrate P (an exposure surface, a photosensitive surface); and an alignment system 91 for detecting alignment marks on the substrate P.

The mask M includes a reticle formed with a device pattern which is projected onto the substrate P. The substrate P includes: a base material such as a glass plate; and a photosensitive film formed on the base material (a coated photosensitive agent). In the present embodiment, the substrate P includes a large-size glass plate. The substrate P has a side length of, for example, 500 mm or more. In the present embodiment, a rectangular glass plate with a side length of approximately 3000 mm is used as a base material of the substrate P. In other embodiments, the length of a side of the substrate P can be 750, 1000, 1500, 2000, 2500, or 3500 mm or more.

The body 5 includes: bases 9; a surface plate 10 arranged on the bases 9; a first column 11 arranged on the surface plate 10; and a second column 12 arranged on the first column 11.

In the present embodiment, the body 5 supports the projection system PS, the mask stage 1, and the substrate stage 2. In the present embodiment, the projection system PS is supported by the first column 11 via the surface plate 13. The mask stage 1 is supported so as to be movable with respect to the second column 12. The substrate stage 2 is supported so as to be movable with respect to the surface plate 10.

In the present embodiment, the vibration control apparatus 6 includes a damping apparatus 26 that has: a vibration transmission mechanism 20; and a damping mechanism 21, which will be described in detail later. Furthermore, the vibration control apparatus 6 includes vibration isolation apparatuses 22 that support the body 5 arranged on a support surface (for example, a floor surface) FL in, for example, a clean room and suppress a vibration transmission between the support surface FL and the body 5.

The vibration control apparatus 6 suppresses a vibration of the body 5 including the bases 9, the surface plate 10, the first column 11, and the second column 12. When a heavy vibration due to, for example, an earthquake or the like acts on the body 5 of the exposure apparatus EX to vibrate the body 5, the vibration suppression apparatus 6 suppresses a vibration of the vibrated body 5.

In the present embodiment, the projection system PS has a plurality of projection optical systems PL. The illumination system IS has a plurality of illumination modules IL corresponding to the plurality of projection optical systems PL. Furthermore, the exposure apparatus EX of the present embodiment projects an image of the pattern of the mask M onto the substrate P while the mask M and the substrate P are synchronously moved in a predetermined scanning direction. That is, the exposure apparatus EX of the present embodiment is a so-called multi-lens type scanning exposure apparatus.

In the present embodiment, the projection system PS has seven projection optical systems PL, and the illumination system IS has seven illumination modules IL. Note that the number of the projection optical systems PL and the illumination modules IL is not limited to seven. In other embodiments, for example the projection system PS can have 11 projection optical systems PL, and the illumination system IS can have 11 illumination modules IL.

The illumination system IS is capable of irradiating the exposure beams EL onto predetermined illumination regions. Each illumination region is included in each irradiation regions of each exposure beam EL radiated from each illumination module IL. In the present embodiment, the illumination system IS illuminates seven different illumination regions with the respective exposure beams EL. The illumination system IS illuminates the portions of the mask M that are arranged in the illumination regions with the exposure beams EL of a uniform luminance distribution. In the present embodiment, for the exposure beams EL irradiated from the illumination system IS, for example emission lines (g-line, h-line, i-line) irradiated for example from a mercury lamp 8 are used.

The mask stage 1 is movable with respect to the illumination regions while holding the mask M. The mask stage 1 holds the mask M so that a bottom surface of the mask M (a pattern forming surface) is substantially parallel with the XY plane. The drive system 3 includes, for example, a linear motor, and is capable of moving the mask stage 1 on a guide surface 12G of the second column 12. In the present embodiment, the mask stage 1 is movable, while holding the mask M, on the guide surface 12G in the three directions of: the X axis, Y axis, and θZ directions by means of activation of the drive system 3.

The projection system PS is capable of irradiating the exposure beams EL onto predetermined projection regions. The projection regions correspond to the irradiation regions of the exposure beams EL radiated from the projection optical systems PL. In the present embodiment, the projection system PS projects the image of the pattern onto the seven different projection regions. The projection optical system PS projects the image of the pattern of the mask M onto portions of the substrate P that are arranged in the projection regions at a predetermined projection magnification.

The substrate stage 2 is movable with respect to the projection regions while holding the substrate P. The substrate stage 2 holds the substrate P so that a surface of the substrate P (an exposure surface) is substantially parallel with the XY plane. The drive system 4 includes, for example, a linear motor, and is capable of moving the substrate stage 2 on a guide surface 10G of the surface plate 10. In the present embodiment, the substrate stage 2 is movable, while holding the substrate P, on the guide surface 10G in the six directions of: the X axis, Y axis, Z axis, θX, θY, and θZ directions, by means of activation of the drive system 4.

The interference system 61 has: a laser interferometer unit 61A for measuring position information of the mask stage 1; and a laser interferometer unit 61B for measuring position information of the substrate stage 2. The laser interferometer unit 61A is capable of measuring position information of the mask stage 1 by use of a measurement mirror 1R arranged on the mask stage 1. The laser interferometer unit 61B is capable of measuring position information of the substrate stage 2 by use of a measurement mirror 2R arranged on the substrate stage 2.

In the present embodiment, the interference system 61 is capable of respective measuring position information of the mask stage 1 and the substrate stage 2 in the X axis, Y axis, and θX directions by use of the laser interferometer units 61A, 61B.

The first detection system 71 detects a position of the bottom surface of the mask M (the pattern forming surface) in the Z axis direction. The first detection system 71 is a so-called multipoint focus leveling detection system on the oblique incidence system, and has a plurality of detectors that are arranged so as to face the bottom surface of the mask M held on the mask stage 1.

The second detection system 81 detects a position of the surface of the substrate P (the exposure surface) in the Z axis direction. The second detection system 81 is a so-called multipoint focus leveling detection system on the oblique incidence system, and has a plurality of detectors that are arranged so as to face the surface of the substrate P held on the substrate stage 2.

The alignment system 91 detects alignment marks provided on the substrate P. The alignment system 91 is a so-called alignment system on the off-axis system, and has a plurality of detectors that are arranged so as to face the surface of the substrate P held on the substrate stage 2.

As shown in FIG. 2, the shape of the surface plate 10 within the XY plane is rectangular. Furthermore, in the present embodiment, the body 5 has two bases 9. In the following description, of the two bases 9, one base 9 is appropriately referred to as a first base 9A, and the other base 9 is appropriately referred to as a second base 9B.

In the present embodiment, the first base 9A supports a bottom surface of the surface plate 10 in the vicinity of an edge of the surface plate 10 on the +Y side. The second base 9B supports the bottom surface of the surface plate 10 in the vicinity of an edge of the surface plate 10 on the −Y side. The bottom surface of the surface plate 10 is a surface that faces in the direction opposite to the guide surface 10G. In the present embodiment, the guide surface 10G of the surface plate 10 is substantially parallel with the XY plane, and faces in the +Z direction. The bottom surface of the surface plate 10 is substantially parallel with the XY plane, and faces in the −Z direction.

In the present embodiment, the vibration control apparatus 6 has fourth vibration isolation apparatuses 22. Each vibration isolation apparatus 22 is arranged at a predetermined position on the support surface FL. The first base 9A is supported by two of the vibration isolation apparatuses 22. The second base 9B is supported by the other two of the vibration isolation apparatuses 22. In other embodiments, the number of the vibration isolation apparatuses 22 can be equal to or less than 3, or can be equal to or greater than 5.

In the following description, of the two vibration isolation apparatuses 22 that support the first base 9A, one vibration isolation apparatus 22 is appropriately referred to as a first vibration isolation unit 22A, and the other vibration isolation apparatus 22 is appropriately referred to as a second vibration isolation unit 22B. In addition, in the following description, of the two vibration isolation apparatuses 22 that support the second base 9B, one vibration isolation apparatus 22 is appropriately referred to as a third vibration isolation unit 22C, and the other vibration isolation apparatus 22 is appropriately referred to as a fourth vibration isolation unit 22D.

In the present embodiment, the first vibration isolation unit 22A supports a bottom surface of the first base 9A in the vicinity of an edge of the first base 9A on the −X side, and the second vibration isolation unit 22B supports the bottom surface of the first base 9A in the vicinity of an edge of the first base 9A on the +X side. The third vibration isolation unit 22C supports a bottom surface of the second base 9B in the vicinity of an edge of the second base 9B on the −X side, and the fourth vibration isolation unit 22D supports the bottom surface of the second base 9B in the vicinity of an edge of the second base 9B on the +X side. Note that the bottom surfaces of the first and second bases 9A, 9B are surfaces capable of being opposed to the support surface FL, and face in the +Z direction. The first and second vibration isolation unit 22A, 22B are arranged between the support surface FL and the bottom surface of the first base 9A. The third and fourth vibration isolation unit 22C, 22D are arranged between the support surface FL and the bottom surface of the second base 9B.

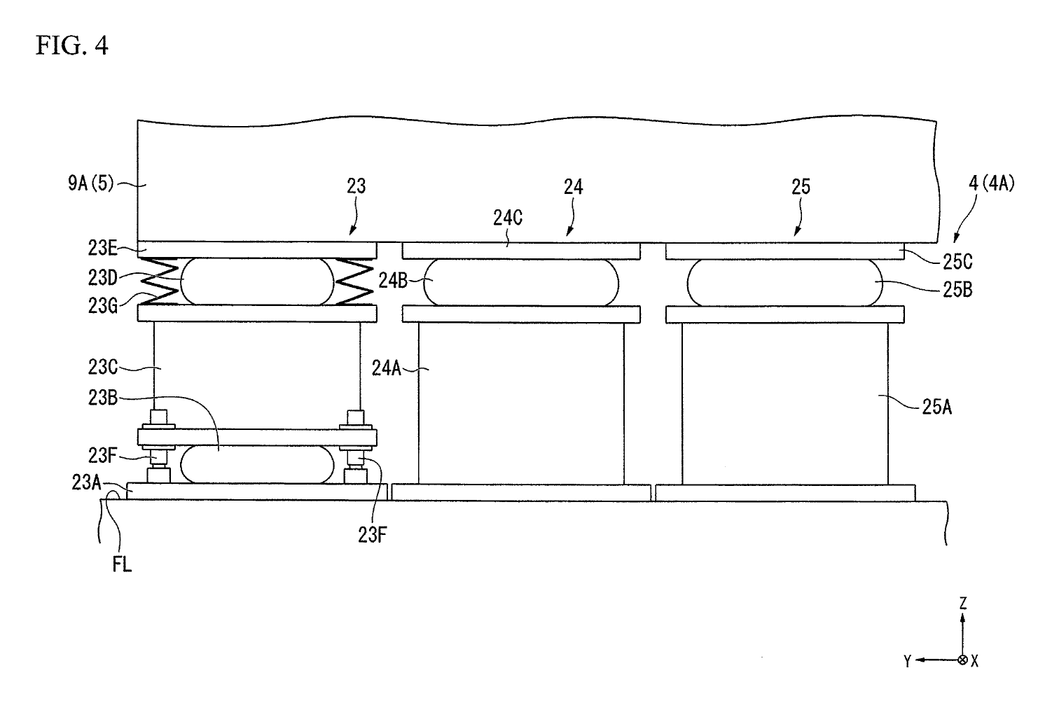

FIG. 4 is a diagram showing an example of the first vibration isolation unit 22A. Note that the first to fourth vibration isolation units 22A to 22D have a similar construction. Below, the first vibration isolation unit 22A will be mainly described, and description of the second to fourth vibration isolation units 22B to 22D will be simplified or omitted.

The first vibration isolation unit 22A has: a first mount 23; a second mount 24; and a third mount 25. In the present embodiment, the first, second, and third mounts 23, 24, and 25 include a gas actuator (a gas spring), and are actively controlled by the control apparatus 7.

The first mount 23 has: a plate member 23A arranged on the support surface FL; a gas spring 23B arranged on the plate member 23A; a rod-like support member 23C arranged on the gas spring 23B; a gas spring 23D arranged on the support member 23C; and a plate member 23E arranged on the gas spring 23D and connected to the first base 9A (the body 5). The support member 23C has: a bottom surface that faces the gas spring 23B; and a top surface that faces the gas spring 23D. The gas spring 23B is arranged between a top surface of the plate member 23A and a bottom surface of the support member 23C. The gas spring 23D is arranged between a top surface of the support member 23C and a bottom surface of the plate member 23E. The gas spring 23B mainly functions as a height adjustment mechanism for adjusting a height of the first base 9A. The gas spring 23D mainly functions as a vibration removal mechanism for suppressing transmission of the vibration of the support surface FL to the first base 9A. The top surface of the plate member 23A and the bottom surface of the support member 23C are coupled by a plurality of coupling members 23F. The top surface of the support member 23C and the bottom surface of the plate member 23E are connected by a bellows member 23G.

The second mount 24 has: a rod-like support member 24A arranged on the support surface FL; a gas spring 24B arranged on the support member 24A; and a plate member 24C arranged on the gas spring 24B and connected to the first base 9A (the body 5). The support member 24A has: a bottom surface that faces the support surface FL; and a top surface that faces the gas spring 24B. The gas spring 24B is arranged between the top surface of the support member 24A and a bottom surface of the plate member 24C. The gas spring 24B functions as a height adjustment mechanism for adjusting a height of the first base 9A and as a vibration removal mechanism for suppressing transmission of the vibration of the support surface FL to the first base 9A.

The third mount 25 has: a rod-like support member 25A arranged on the support surface FL; a gas spring 25B arranged on the support member 25A; and a plate member 25C arranged on the gas spring 25B and connected to the first base 9A (the body 5). The support member 25A has: a bottom surface that faces the support surface FL; and a top surface that faces the gas spring 25B. The gas spring 25B is arranged between the top surface of the support member 25A and a bottom surface of the plate member 25C. The gas spring 25B functions as a height adjustment mechanism for adjusting a height of the first base 9A and as a vibration removal mechanism for suppressing transmission of the vibration of the support surface FL to the first base 9A.

As shown in FIG. 1 and FIG. 2, the vibration control apparatus 6 has four damping apparatuses 26, each of which includes a vibration transmission mechanism 20 and a damping mechanism 21. The damping apparatuses 26 include: two damping apparatuses 26 that face a side surface of the first base 9A on the +Y side; and the other two damping apparatuses 26 that face a side surface of the second base 9B on the −Y side.

In the following description, of the two damping apparatuses 26 that face the side surface of the first base 9A, one of the damping apparatuses 26 is appropriately referred to as a first damping unit 26A, and the other of the damping apparatuses 26 is appropriately referred to as a second damping unit 26B. Furthermore, in the following description, of the two damping apparatuses 26 that face the side surface of the second base 9B, one of the damping apparatuses 26 is appropriately referred to as a third damping unit 26C, and the other of the damping apparatuses 26 is appropriately referred to as a fourth damping unit 26D.

As shown in FIG. 1 and FIG. 2, the damping apparatuses 26 including the vibration transmission mechanism 20 and the damping mechanism 21 are arranged at positions on the support surface FL different from the arrangement positions of the vibration isolation apparatuses 22. In other words, the damping apparatus 26 is arranged at a position on the support surface FL, different from an arrangement position of the vibration isolation apparatus 22.

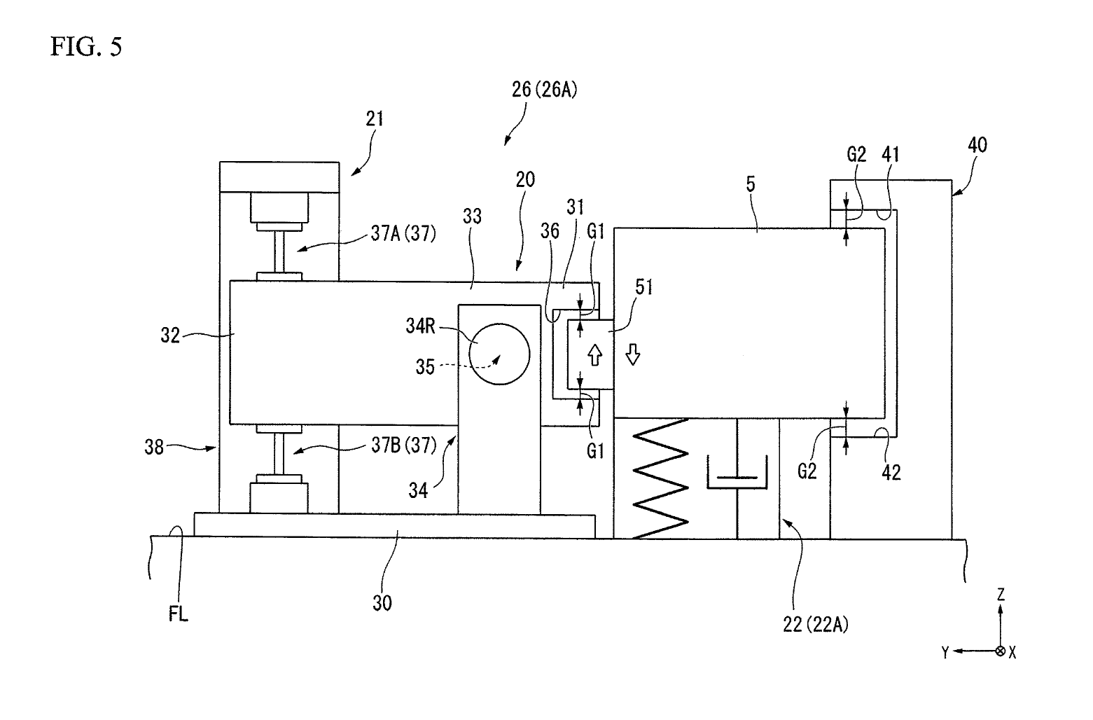

FIG. 5 is a diagram showing an example of the first damping unit 26A. Note that the first to fourth damping units 26A to 26D have a similar construction. Below, the first damping unit 26A will mainly be described, and description of the second to fourth damping units 26B to 26D will be simplified or omitted. In FIG. 5, illustration of the body 5 and the first vibration isolation apparatus 22A is simplified.

When the body 5 is vibrated in a predetermined vibration direction, the vibration control apparatus 6 including the damping apparatuses 26 and the vibration isolation apparatuses 22 suppress the vibration of the body 5 in the vibration direction. The following description will be for the case where the vibration direction of the body 5 is in a supporting direction (the Z axis direction in the embodiment) for the body 5 by the vibration isolation apparatuses 22 by way of example. Note that the vibration direction can include other directions such as the θX direction.

The first damping unit 26A includes: a vibration transmission mechanism 20 connected to a body 5, which vibrates due to, for example, an inland earthquake or the like, and vibrating in conjunction with the body 5; and a damping mechanism 21 that damps the vibration of the vibration transmission mechanism 20. The vibration transmission mechanism 20 has a first portion 31 that is connected to the body 5, which vibrates in a predetermined vibration direction with a second amplitude H2 larger than a first amplitude H1 (a predetermined expected amplitude H1), to thereby vibrate with the second amplitude H2 in conjunction with the vibration of the body 5, and having a second portion 32 different from the first portion 31, vibration transmission mechanism 20 causing the first portion 31 and the second portion 32 to vibrate in conjunction with each other. The damping mechanism 21 is connected to the second portion 32, to thereby reduce the amplitude of the second portion 32 to not more than a third amplitude H3 corresponding to the first amplitude H1. The damping mechanism 21 damps the vibration of a second portion 32, to thereby reduce the amplitude of a first portion 31, which is moved in conjunction with the second portion 32, to an amplitude equal to or less than the first amplitude H1. The first portion 31 and the second portion 32 are substantially dynamically coupled with each other. It is possible for the first portion 31 to abut the vibrating body 5.

The vibration transmission mechanism 20 has: a rod-like lever member 33 longer in the Y axis direction; and a support mechanism 34 that supports a predetermined section 35 of the lever member 33 rotatably. The support mechanism 34 has a rotation shaft 34R, and rotatably supports the predetermined section 35 by means of the rotation shaft 34R. The first portion 31 is provided to a first end portion of the lever member 33 close to the body 5. The second portion 32 is provided to a second end portion of the lever member 33. A predetermined section 35 is located in the lever member 33 between the first end portion (the first portion 31) and the second end portion (the second portion 32).

The support mechanism 34 is supported on the support surface FL via the plate member 30. In the present embodiment, the first portion 31 is an end portion of the lever member 33 on the −Y side. The second portion 32 is an end portion of the lever member 33 on the +Y side. The first portion 31 and the second portion 32 are substantially rigidly connected to each other, and hence, are substantially unified. The support mechanism 34 rotatably supports the predetermined section 35 between the first portion 31 and the second portion 32, so that the first portion 31 and the second portion 32 are in a state of being capable of rotating in a predetermined vibration direction. In other words, the vibration transmission mechanism 20 vibrates in the vibration direction the lever member 33, which is rotatably supported by the support mechanism 34, with the end portion on the −Y side and the end portion on the +Y side of the lever member 33 as the first portion 31 and the second portion 32, respectively.

In the present embodiment, the predetermined section 35 of the lever member 33 supported by the support mechanism 34 is provided at closer to the first portion 31 than a middle position (midpoint, middle point) between the first portion 31 and the second portion 32. The vibration transmission mechanism 20 vibrates the second portion 32 with a larger amplitude than the first portion 31 (in other words, an amplitude of the first portion 31 multiplied by a predetermined enlargement magnification). That is, in the vibration transmission mechanism 20, the second portion 32 has a larger amplitude than an amplitude of the first portion 31.

In the present embodiment, the lever member 33 has a recess portion 36 in the first portion 31. The body 5 has a protrusion portion 51 that is arranged on an inner side of the recess portion 36 of the first portion 31. The protruding portion 51 is provided, for example, at a side surface portion of the base(s) 9 or the surface plate 10, of the body 5. In the state with the body 5 not being vibrated, an inner surface (an inner side surface) of the recess portion 36 and an outer surface (an outer side surface) of the protrusion portion 51 are spaced a predetermined spacing G1 (a gap, clearance (a first clearance)) away from each other. In the present embodiment, the first amplitude H1 is substantially the same as the spacing G1. That is, in the state with the body 5 not being vibrated, the first portion 31 (the recess portion 36) of the lever member 33 is spaced the spacing G1 equal to the first amplitude H1 away from the body 5 (the protrusion portion 51) with respect to the vibration direction. Between the first portion 31 and the body 5, the clearance G1 (the first clearance) based on the predetermined expected amplitude (the first amplitude H1) of the body 5 is provided.

For example, in the case where a vibration attending an inland earthquake or the like acts on the body 5 to vibrate the body 5 in the Z axis direction, the first portion 31 (the inner surface of the recess portion 36) of the lever member 33 is not brought into contact with the body 5 (the outer surface of the protrusion portion 51) if the amplitude of the body 5 in the vibration direction is less than the first amplitude H1. On the other hand, if the body 5 vibrates in the vibration direction with the second amplitude H2 larger than the first amplitude H1, the first portion 31 (the inner surface of the recess portion 36) of the lever member 33 is brought into contact with the body 5 (the outer surface of the protrusion portion 51). In this case, in the state of being connected to the body 5 vibrating with the second amplitude H2, the first portion 31 of the lever member 33 vibrates substantially with the second amplitude H2 in conjunction with the vibration of the body 5.

With the vibration of the first portion 31 of the lever member 33, the second portion 32 also vibrates in conjunction with the first portion 31. In this case, the amplitude of the second portion 32 is larger than the amplitude of the first portion 31.

The damping mechanism 21 is connected to the second portion 32 for reducing the amplitude of the second portion 32. The damping mechanism 21 includes shock absorbers (shock absorbing mechanisms) 37 provided extendably along the vibration direction. The shock absorber 37 extends and contracts in accordance with the vibration of the second portion 32.

In the present embodiment, the shock absorbers 37 include: a first shock absorber 37A connected to a top surface of the second portion 32; and a second shock absorber 37B connected to a bottom surface of the second portion 32. The damping mechanism 21 has a support mechanism 38 that supports the first shock absorber 37A and the second shock absorber 37B. The support mechanism 38 is supported on the support surface FL via the plate member 30. The first shock absorber 37A suppresses the movement of the second portion 32 in the +Z direction, to thereby reduce the amplitude of the second portion 32. The second shock absorber 37B suppresses the movement of the second portion 32 in the −Z direction, to thereby reduce the amplitude of the second portion 32.

If the amplitude of the body 5 in the vibration direction (the Z axis direction) is equal to or less than the first amplitude H1, the vibration of the body 5 is suppressed through active vibrational isolation control by the vibration isolation apparatuses 22 under control by the control apparatus 7. In this case, the vibrational isolation of the body 5 is controlled by the vibration isolation apparatuses 22 without receiving actions from the vibration damping apparatuses 26 in a state with the body 5 being substantially independent of the vibration damping apparatuses 26.

Furthermore, the vibration control apparatus 6 of the present embodiment includes: an amplitude limitation mechanism 40 that is spaced a predetermined spacing G2 (a gap, clearance (s second clearance)) larger than the first amplitude H1 away from the body 5 in the vibration direction in the state with the body 5 not being vibrated, and prevents the body 5 from vibrating with an amplitude not less than the predetermined spacing G2. Between the amplitude limitation mechanism 40 and the body 5, the second clearance larger than the first clearance is provided. The amplitude limitation mechanism 40 has: a first surface 41 that faces a top surface of a part of the body 5; and a second surface 42 that faces a bottom surface of a part of the body 5. The first surface 41 is a surface that faces in the −Z direction. The second surface 42 is a surface that faces in the +Z direction.

Next is a description of an example of operation of the exposure apparatus EX with the above construction. After the mask M is supported on the mask stage 1 and the substrate P is supported on the substrate stage 2, the control apparatus 7 starts an exposure process on the substrate P. The control apparatus 7 radiates the exposure beams EL from the illumination system IS to illuminate the mask M supported on the mask stage 1 with the exposure beams EL. The image of the pattern of the mask M illuminated with the exposure beams EL is projected onto the substrate P supported on the substrate stage 2. Thereby, the pattern is transferred to the substrate P.

As described above, the exposure apparatus EX is a multi-lens type scanning exposure apparatus. The control apparatus 7 controls the mask stage 1 and the substrate stage 2 to illuminate the mask M with the exposure beams EL while synchronously moving the mask M and the substrate P in the scanning direction, to thereby expose the substrate P with the exposure beams EL via the pattern of the mask M. In the present embodiment, the scanning direction (the synchronous movement direction) of the substrate P is made the X axis direction, and the scanning direction (the synchronous movement direction) of the mask M is also made the X axis direction. While moving the substrate P in the X axis direction with respect to the projection regions of the projection system PS and also moving the mask M in the X axis direction with respect to the illumination regions of the illumination system IS synchronously with the movement of the substrate P in the X axis direction, the control apparatus 7 irradiates the exposure beams EL onto the illumination regions, to thereby irradiate the exposure beams EL from the mask M onto the projection regions via the projection apparatus PS. As a result, the substrate P is exposed by the exposure beams EL irradiated onto the projection regions via the mask M and the projection system PS, and the pattern of the mask M is transferred onto the substrate P.

During exposure of the substrate P, the vibration transmission between the support surface FL and the body 5 is suppressed by the vibration isolation apparatuses 22. As a result, the pattern is favorably transferred onto the substrate P. At this time, the vibrational isolation of the body 5 is controlled by the vibration isolation apparatus 22 without receiving actions from the vibration damping apparatuses 26.

At the same time, there is a possibility that, for example, a heavy vibration attending an inland earthquake or the like acts on the body 5 via the support surface FL to strongly vibrate the body 5.

In the present embodiment, the vibration control apparatus 6 including the damping apparatuses 26 is provided. Therefore, the body 5 is suppressed from heavily vibrating. That is, even in the case where the body 5 is strongly vibrated, the body 5 is suppressed from vibrating by the vibration control apparatus 6. To be more specific, the vibration damping apparatuses 26 effectively suppress a vibration with a larger amplitude than the amplitude H1 being applied to the body 5.

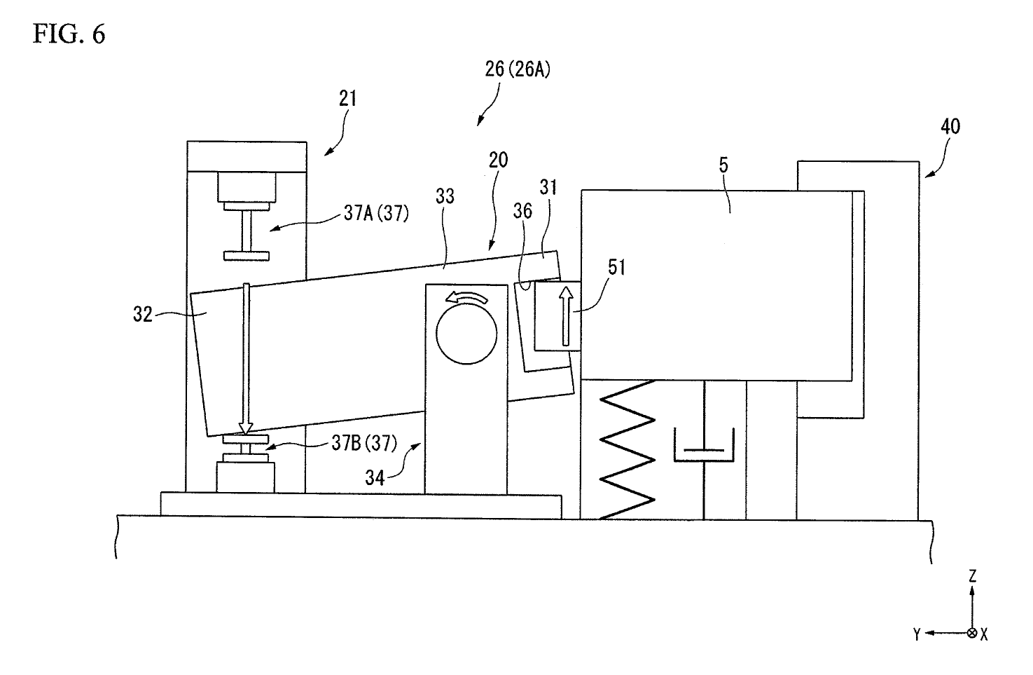

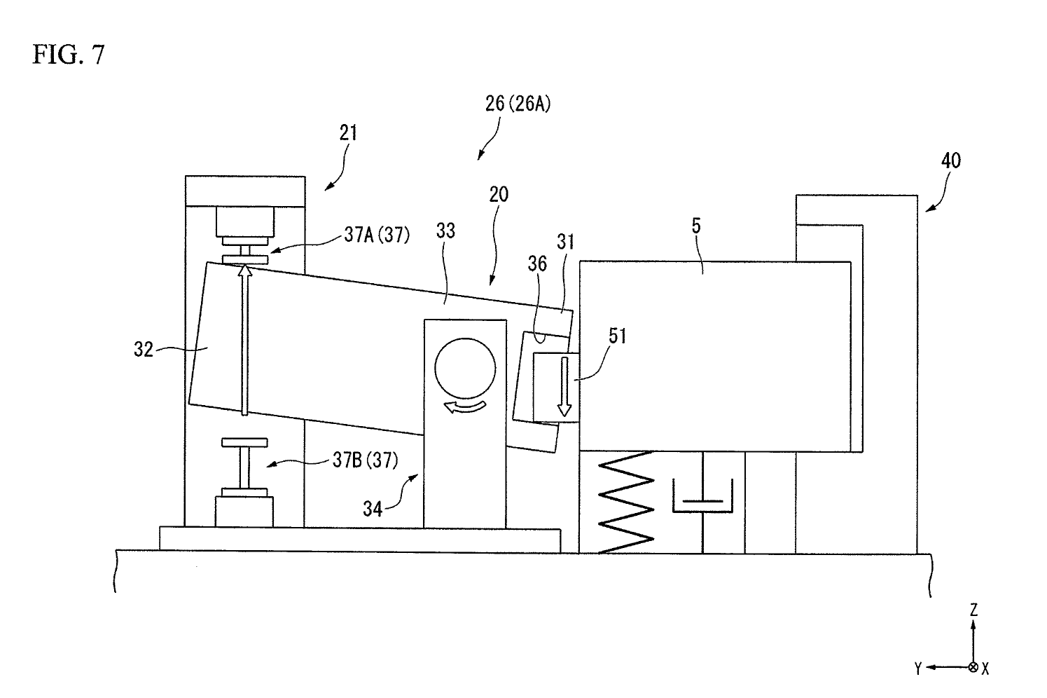

FIG. 6 is a schematic diagram showing a state where the body 5 is vibrated to be moved in the +Z direction with respect to the support surface FL. FIG. 7 is a schematic diagram showing a state where the body 5 is vibrated to be moved in the −Z direction.

With the body 5 vibrating in the vibration direction with the second amplitude H2 larger than the first amplitude H1, the inner surface of the recess portion 36 of the first portion 31 is brought into contact with the outer surface of the protrusion portion 51 of the body 5 as shown in FIG. 6 and FIG. 7. As a result, the first portion 31 is connected to the body 5 (the protrusion portion 51) vibrating with the second amplitude H2, to thereby vibrate with the second amplitude H2 in conjunction with the vibration of the body 5.

With the vibration of the first portion 31, the second portion 32 vibrates with an amplitude larger than the first portion 31. If the first portion 31 vibrates with the second amplitude H2, then the second portion 32 vibrates with an amplitude larger than the second amplitude H2.

The amplitude of the second portion 32 that vibrates with an amplitude larger than the second amplitude H2 is reduced by the damping mechanism 21. The damping mechanism 21 reduces the amplitude of the second portion 32 to not more than the third amplitude H3 that corresponds to the first amplitude H1. That is, the damping mechanism 21 has the first shock absorber 37A and the second shock absorber 37B, and is capable of absorbing the energy of the second portion 32 moving in the vibration direction to sufficiently reduce the amplitude of the second portion 32. The damping mechanism 21 has a rate of damping based on the first amplitude H1, and absorbs the kinetic energy of the second portion 32. The rate of damping corresponds to reducing the amplitude of the second portion 32 to not more than the third amplitude H3 that corresponds to the first amplitude H1. With the amplitude of the second portion 32 being sufficiently reduced, the amplitude of the first portion 31 is sufficiently reduced.

The amplitude of the second portion 32 changes according to a ratio between the distance from the predetermined section 35 to the first portion 31 and the distance from the predetermined section 35 to the second portion 32 (magnification of amplitude transmission) and according to the amplitude of the first portion 31. Therefore, with the damping mechanism 21 reducing the amplitude of the second portion 32 to not more than the third amplitude H3 that corresponds to the first amplitude H1, the amplitude of the first portion 31 becomes less than the first amplitude H1. That is, with the damping mechanism 21 reducing the amplitude of the second portion 32 to not more than the third amplitude H3, a state is brought about in which the inner surface of the recess portion 36 of the first portion 31 is not in contact with the outer surface of the protrusion portion 51 of the body 5.

In this manner, according to the present embodiment, the vibration control apparatus 6 including the vibration transmission mechanism 20 and the damping mechanism 21 is provided. Therefore, even in the case where, for example, a heavy vibration (i.e., a vibration with an amplitude larger than the first amplitude H1) attending an earthquake or the like acts on the body 5, the body 5 is suppressed from vibrating excessively (with a large amplitude).

Furthermore, the amplitude limitation mechanism 40 is provided. Therefore, for example, even if the body 5 vibrates excessively (with a large amplitude) and the energy with which the second portion 32 moves fails to be sufficiently absorbed by the damping mechanism 21, the body 5 can be suppressed from vibrating excessively by the amplitude limitation mechanism 40. Furthermore, if an amplitude not more than the first amplitude H1 acts on the body 5, it is possible to suppress the vibration transmission to the body 5 through active vibrational isolation control by the vibration isolation apparatuses 22.

As described above, according to the present embodiment, the vibration control apparatus 6 including the vibration transmission mechanism 20 and the damping mechanism 21 is provided. Therefore, even in the case where a heavy vibration attending an earthquake or the like acts on the exposure apparatus EX, the body 5 is suppressed from vibrating heavily. Consequently, it is possible to suppress an occurrence of serious damage in the exposure apparatus EX.

Furthermore, in the present embodiment, the first portion 31 is spaced the spacing GI equal to the first amplitude H1 away from the body 5 in the state with the body 5 not being vibrated. That is, in the state with the body 5 not being vibrated, the first portion 31 and the body 5 are spaced from each other. Therefore, in a state where the body 5 is not vibrated, that is, in a normal state where there is no occurrence of an earthquake or the like, the vibration isolating action of the vibration isolation apparatuses 22 is not prevented. Consequently, in the normal state, it is possible to favorably expose the substrate P while suppressing the vibration of the body 5 by means of the vibration isolation apparatuses 22.

Furthermore, in the present embodiment, the vibration transmission mechanism 20 vibrates the second portion 32 with an amplitude larger than that of the first portion 31. As a result, it is possible to sufficiently exert the performance of the shock absorber 37. Then, the shock absorber 37 whose performance is sufficiently exerted is used to sufficiently reduce the amplitude of the second portion 32. Thereby, it is possible to further reduce the amplitude of the first portion 31. The vibration transmission mechanism 20 is capable not only of vibrating the second portion 32 with an amplitude larger than that of the first portion 31 but also of vibrating the second portion 32 with an amplitude equal to or less than that of the first portion 31 in accordance with the performance of the shock absorber 37. That is, in the vibration control apparatus 6, the vibration transmission mechanism 20 is capable of vibrating, in conjunction with the first portion 31, the second portion with an amplitude of the first portion 31 multiplied by a predetermined magnification (enlargement magnification, reduction magnification, or equal magnification), and the damping mechanism 21 is capable of reducing the amplitude of the vibration of the second portion 32 to a value equal to or less than an amplitude of the first amplitude H1 multiplied by the predetermined magnification.

Furthermore, in the vibration transmission mechanism 20 that moves the first portion 31 and the second portion 32 in conjunction with each other, it is possible to use, for example, a hinge mechanism that swingably supports the lever member 33 instead of the support mechanism 34 that rotatably supports lever member 33. In this case, it is preferable that the hinge mechanism be constructed, for example, to support a bottom portion of the lever member 33 between the first end portion provided with the first portion 31 and the second end portion provided with the second portion 32.

Note that, as for the aforementioned substrate P, not only a semiconductor wafer for manufacturing a semiconductor device, but also a glass substrate for a display device, a ceramic wafer for a thin film magnetic head, or a master mask or reticle (synthetic quartz or silicon wafer), etc. can be used.

As for the exposure apparatus EX, in addition to a step-and-scan type exposure apparatus (scanning stepper) in which while synchronously moving the mask M and the substrate P, the pattern of the mask M is scan-exposed, a step-and-repeat type projection exposure apparatus (stepper) in which the pattern of the mask M is exposed in a batch in the state with the mask M and the substrate P being stationary, and the substrate P is successively moved stepwise can be used.

Furthermore, in the step-and-repeat type projection exposure, after a reduced image of a first pattern is transferred onto the substrate P by using the projection optical system in the state with the first pattern and the substrate P being substantially stationary, a reduced image of a second pattern may be exposed in a batch on the substrate P, partially overlapped on the first pattern by using the projection optical system, in the state with the second pattern and the substrate P being substantially stationary (a stitch type batch exposure apparatus). As the stitch type exposure apparatus, a step-and-stitch type exposure apparatus in which at least two patterns are transferred onto the substrate P in a partially overlapping manner, and the substrate P is sequentially moved can be used.

Furthermore, the present invention can also be applied to an exposure apparatus such as disclosed for example in U.S. Pat. No. 6,611,316, which combines patterns of two masks on a substrate via a projection optical system, and double exposes a single shot region on the substrate at substantially the same time, in a single scan exposure.

Furthermore, the present invention can also be applied to a proximity type exposure apparatus, a mirror projection analyzer, and the like. In the case of a proximity type exposure apparatus, the body supports at least one of the mask stage and the substrate stage.

Furthermore, the present invention can also be applied to a twin stage type exposure apparatus provided with a plurality of substrate stages such as disclosed in U.S. Pat. No. 6,341,007, U.S. Pat. No. 6,208,407, and U.S. Pat. No. 6,262,796.

Moreover, the present invention can also be applied to an exposure apparatus provided with: a substrate stage for holding a substrate; and a measurement stage on which a reference member formed with a reference mark and/or various photoelectronic sensors are mounted and which does not hold the substrate to be exposed, such as disclosed for example in U.S. Pat. No. 6,897,963, and U.S. Patent Application Publication No. 2007/0127006.

The types of exposure apparatuses EX are not limited to exposure apparatuses for semiconductor element manufacture that expose a semiconductor element pattern onto a substrate P, but are also widely applicable to exposure apparatuses for the manufacture of liquid crystal display elements and for the manufacture of displays, and exposure apparatuses for the manufacture of thin film magnetic heads, image pickup devices (CCDs), micro machines, MEMS, DNA chips, and reticles or masks.

Furthermore, in the aforementioned respective embodiments, as a light source apparatus for producing an excimer laser beam as the exposure beam EL, an ArF excimer laser may be used. However, for example, a harmonic generation device as disclosed in U.S. Pat. No. 7,023,610 that includes: a fixed laser light source such as a DFB semiconductor laser or a fiber laser; an optical amplification section having a fiber amplifier or the like; and a wavelength conversion section, and that outputs pulse light of wavelength 193 nm may be used. Furthermore, in the above embodiment, the aforementioned illumination regions and projection regions have a rectangular shape. However, another shape such as a circular shape may be adopted.

In the aforementioned respective embodiments, an optical transmission type mask formed with a predetermined shielding pattern (or phase pattern or dimming pattern) on an optical transmission substrate is used. However, instead of this mask, for example as disclosed in U.S. Pat. No. 6,778,257, a variable form mask (also called an electronic mask, an active mask, or an image generator) for forming a transmission pattern or reflection pattern, or a light emitting pattern, based on electronic data of a pattern to be exposed may be used. The variable form mask includes, for example, a DMD (a digital micro-mirror device), which is a kind of non-luminous type image display element (spatial light modulator), and the like. Furthermore, instead of the variable form mask provided with a non-luminous type image display element, a pattern formation apparatus including a self-luminous type image display element may be provided. As a self-luminous type image display element, for example a CRT (a cathode ray tube), an inorganic light emitting diode display, an organic light emitting diode (OLED) display, an LED display, an LD display, a field emission display (FED), a plasma display panel (PDP), or the like may be used.

Moreover, in the aforementioned respective embodiments, an exposure apparatus provided with a projection optical systems PL was described as an example. However, the present invention can also be applied to an exposure apparatus and an exposure method which does not use a projection optical system PL.

Furthermore the present invention can also be applied to an exposure apparatus (lithography system) which exposes a line-and-space pattern on a substrate P by forming interference fringes on the substrate P, as disclosed for example in PCT International Patent Publication No. WO 2001/035168.

As described above, the exposure apparatus EX of the present embodiment is manufactured by assembling various subsystems, including the respective constituent elements presented in the Scope of Patents Claims of the present application, so that the prescribed mechanical precision, electrical precision and optical precision can be maintained. To ensure these respective precisions, performed before and after this assembly are adjustments for achieving optical precision with respect to the various optical systems, adjustments for achieving mechanical precision with respect to the various mechanical systems, and adjustments for achieving electrical precision with respect to the various electrical systems. The process of assembly from the various subsystems to the exposure apparatus includes mechanical connections, electrical circuit wiring connections, air pressure circuit piping connections, etc. among the various subsystems. Obviously, before the process of assembly from these various subsystems to the exposure apparatus, there are the processes of individual assembly of the respective subsystems. When the process of assembly to the exposure apparatuses of the various subsystems has ended, overall assembly is performed, and the various precisions are ensured for the exposure apparatus as a whole. Note that it is preferable that the manufacture of the exposure apparatus be performed in a clean room in which the temperature, the degree of cleanliness, etc. are controlled.

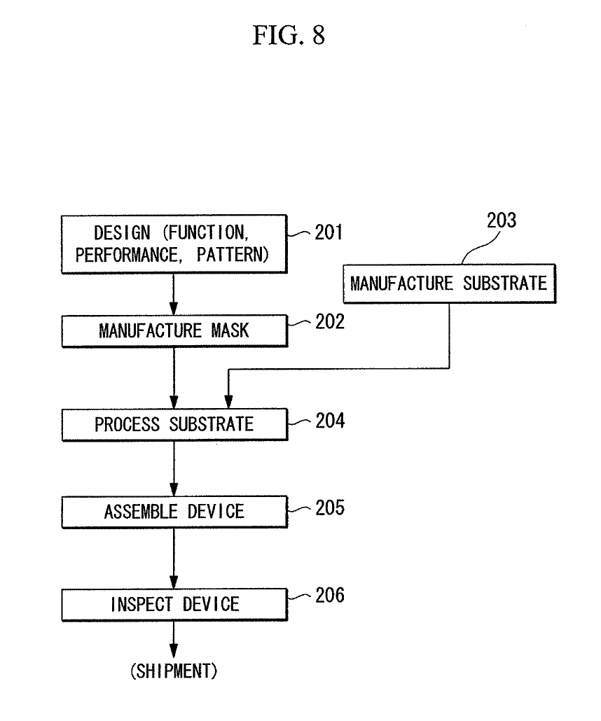

As shown in FIG. 8, microdevices such as semiconductor devices are manufactured by going through: a step 201 that performs microdevice function and performance design; a step 202 that creates the mask (reticle) based on this design step; a step 203 that manufactures the substrate that is the device base material; a substrate processing step 204 including exposing, according to the aforementioned embodiment, the substrate with the exposure beams by use of the pattern of the mask, and developing the exposed substrate; a device assembly step (including treatment processes such as a dicing process, a bonding process and a packaging process) 205; an inspection step 206; and so on. The device assembly step 205 includes treating the substrate onto which the pattern is transferred, correspondingly to the pattern.

In the aforementioned respective embodiments, the description has been for the case where the vibration control apparatus is applied to an exposure apparatus, by way of example. However, the vibration control apparatus can be applied to device manufacturing apparatuses other than an exposure apparatus. For example, the vibration control apparatus described in the aforementioned embodiment can be applied to an ink jet apparatus that supplies ink drops to a substrate to form a device pattern on the substrate. In the case where the ink jet apparatus is provided with: a substrate stage that moves while supporting the substrate; and a body that movably supports the substrate stage, it is possible to favorably manufacture devices by suppressing the vibration of the body.

Note that the requirements of the aforementioned respective embodiments can be appropriately combined. Furthermore, there may be cases where some of the constituent elements are not used. As far as is permitted by the law, the disclosures in all of the Japanese Patent Publications and U.S. Patents related to exposure apparatuses and the like cited in the aforementioned respective embodiments and modified examples, are incorporated herein by reference.

What is claimed is:

1. A vibration control apparatus that controls a vibration of a structure, comprising:
a vibration isolation apparatus that supports the structure and suppresses a transmission of a vibration to the structure, the vibration having an amplitude equal to or less than a first amplitude in a predetermined direction; and
a damping apparatus that damps a vibration of the structure vibrating in the predetermined vibration direction with a second amplitude larger than the first amplitude, to thereby reduce the vibration to equal to or less than the first amplitude.

2. The vibration control apparatus according to claim 1,
wherein the damping apparatus comprises:
a vibration transmission mechanism that is connected to the structure vibrating with the second amplitude and is vibrated in conjunction with the structure; and
a damping mechanism that damps the vibration of the vibration transmission mechanism.

3. The vibration control apparatus according to claim 2, wherein
the vibration transmission mechanism has a first portion that is connected to the structure vibrating with the second amplitude, to thereby vibrate with the second amplitude, and has a second portion that is different from the first portion, the vibration transmission mechanism causing the first portion and the second portion to vibrate in conjunction with each other, and wherein
the damping mechanism is connected to the second portion and damps a vibration of the second portion, to thereby reduce a vibration of the first portion to equal to or less than the first amplitude.

4. The vibration control apparatus according to claim 3, wherein
the vibration transmission mechanism vibrates the second portion with a predetermined amplitude in conjunction with the first portion, the predetermined amplitude being made by multiplying an amplitude of the first portion by a predetermined magnification, and wherein
the damping mechanism reduces the amplitude of the vibration of the second portion to equal to or less than the amplitude which is made by multiplying the first amplitude by the predetermined magnification.

5. The vibration control apparatus according to claim 4, wherein
the vibration transmission mechanism vibrates the second portion with an amplitude larger than that of the first portion.

6. The vibration control apparatus according to claim 3, wherein
the first portion is provided at a distance equal to the first amplitude away from the structure with respect to the vibration direction in a state with the structure not being vibrated.

7. The vibration control apparatus according to claim 3, wherein
the vibration transmission mechanism comprises a lever member, the first and second portions being provided on an first edge part and a second edge part of the lever member, and wherein
a support member support a predetermined part of the lever member between the first edge part and the second edge part so that the first portion and the second portion are capable of rotating in the vibration direction.

8. The vibration control apparatus according to claim 2, wherein
the damping mechanism includes a shock absorbing mechanism that is provided extendably with respect to the vibration direction.

9. The vibration control apparatus according to claim 1, wherein
the vibration isolation apparatus is arranged on a predetermined support surface and supports the structure, and wherein
the damping apparatus is arranged at a position on the support surface, the position being different from an arrangement position of the vibration isolation apparatus.

10. The vibration control apparatus according to claim 1, further comprising
an amplitude limitation mechanism that is spaced a predetermined distance larger than the first amplitude away from the structure with respect to the vibration direction in a state with the structure not being vibrated, and that prevents the structure from vibrating with an amplitude of not less than the predetermined distance.

11. The vibration control apparatus according to claim 1, wherein
the vibration direction is substantially equal to a support direction for the vibration isolation apparatus with respect to the structure.

12. The vibration control apparatus according to claim 1, wherein
the vibration direction is substantially equivalent to a vertical direction.

13. The vibration control apparatus according to claim 1, wherein
the damping apparatus comprises:
a vibration transmission mechanism that has a first portion and a second portion dynamically coupled with each other, the first portion being capable of abutting the structure in vibration; and
a damping mechanism that has a rate of damping based of a predetermined amplitude of the structure and absorbs kinetic energy of the second portion.

14. The vibration control apparatus according to claim 13, wherein
the second portion in the vibration transmission mechanism has an amplitude larger than that of the first portion.

15. The vibration control apparatus according to claim 13, wherein
a first clearance based on the predetermined amplitude is provided between the first portion and the structure.

16. The vibration control apparatus according to claim 15, further comprising:
an amplitude limitation mechanism that prevents a vibration of the structure, a second clearance larger than the first clearance being provided between the amplitude limitation mechanism and the structure.

17. The vibration control apparatus according to claim 13, wherein
the vibration isolation apparatus supports the structure on a predetermined support surface, and wherein
the damping apparatus is arranged at a position on the support surface, the position being different from an arrangement position of the vibration isolation apparatus.

18. A vibration control method of controlling a vibration of a structure, the method comprising:
supporting the structure, and also suppressing transmission of a vibration with an amplitude equal to or less than a first amplitude in a predetermined vibration direction to the structure; and
damping a vibration of the structure that is vibrated with a second amplitude larger than the first amplitude in the vibration direction to a vibration with an amplitude equal to or less than the first amplitude.

19. The vibration control method according to claim 18, wherein
the damping a vibration of the structure comprises:
vibrating a predetermined member in conjunction with the structure vibrating with the second amplitude and
damping a vibration of the predetermined member.

20. The vibration control method according to claim 19, wherein:
the vibrating a predetermined member comprises: connecting a first portion of the predetermined member to the structure vibrating with the second amplitude to vibrate the first portion with the second amplitude; and vibrating a second portion of the predetermined member different from the first portion in conjunction with the first portion; and
the damping a vibration of the predetermined member comprises damping a vibration of the second portion to reduce an amplitude of the first portion to an amplitude equal to or less than the first amplitude.

21. An exposure apparatus that transfers a pattern formed on a mask onto a substrate, comprising:
a first support portion that supports the mask;
a second support portion that supports the substrate:
a projection optical system that projects an image of the pattern onto the substrate;
a structure that supports at least one of the first support portion, the second support portion, and the projection optical system; and
the vibration control apparatus according to claim 1 for controlling a vibration of the structure.

22. An exposure apparatus that transfers a pattern formed on a mask onto a substrate, comprising:
a first support portion that supports the mask;
a second support portion that supports the substrate:
a structure that supports at least one of the first support portion and the second support portion; and
the vibration control apparatus according to claim 1 for controlling a vibration of the structure.

23. A device manufacturing method, comprising:
transferring the pattern onto the substrate by use of the exposure apparatus according to claim 21; and
treating the substrate onto which the pattern is transferred, correspondingly to the pattern.
